(19) United States
(12) Patent Application Publication
(10) Pub. No.: US 2016/0338206 A1
(43) Pub. Date: Nov. 17, 2016

(54) FLEXIBLE ELECTRODE LAYER AND MANUFACTURING METHOD THEREOF, DISPLAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiuxia YANG, Beijing (CN); Feng BAI, Beijing (CN); Jiantao LIU, Beijing (CN)

(21) Appl. No.: 15/142,781

(22) Filed: Apr. 29, 2016

(30) Foreign Application Priority Data
May 14, 2015 (CN) 201510247050.4

(51) Int. Cl. H05K 3/02; H05K 3/28; G06F 1/16; H01B 1/04

(52) U.S. Cl. CPC H05K 3/027; H01B 1/04; H05K 3/28; G06F 1/1652; H05K 2203/107

(57) ABSTRACT

Embodiments of the present disclosure provide a flexible electrode layer and a manufacturing method thereof, a display substrate and a display device. The manufacturing method of the flexible electrode layer comprises: forming a first electrode layer on a substrate, the first electrode layer being made of carbon nanotube material and/or graphene material; and performing doping modification on the first electrode layer by using an oxidizing material, to form a second electrode layer. Thus, by reducing a resistivity of a material of the flexible electrode layer, a square resistance is relatively small when it is applied to an electrode structure, which meets a requirement of a low resistance value on the electrode structure of a display device, and is conducive to further development of a flexible display.

### TECHNICAL FIELD

Embodiments of the present disclosure relate to a flexible electrode layer and a manufacturing method thereof, a display substrate and a display device.

### BACKGROUND

A flexible display is made of a flexible material, which has deformable and flexible characteristics. The flexible display can implement a variety of functions that cannot be implemented by a conventional rigid display. For example, the flexible display may be folded to put into a pocket and carry about; or the flexible display is “wound off”, to be used as a map; and the flexible display may also be embedded in glasses, clothes, a watch, a helmet, and other daily necessities to become a wearable electronic device. Thus, the flexible display has a huge market potential, and becomes a main trend of development of a current display technology.

One of difficulties in implementing the flexible display is to form a flexible electrode such as a pixel electrode having flexibility. Therein, Indium Tin Oxide (ITO) and Indium Zinc Oxide (IZO) applied to an electrode structure of the conventional rigid display have a greater mechanical strength and a poorer flexibility, which are difficult to be properly applied to the flexible display.

### SUMMARY

Embodiments of the present disclosure provide a flexible electrode layer and a manufacturing method thereof, a display substrate and a display device, by reducing a resistivity of a material of the flexible electrode layer, a square resistance is relatively small when it is applied to an electrode structure, which meets a requirement of a low resistance value on the electrode structure of a display device, and is conducive to further development of a flexible display.

In one aspect, an embodiment of the present disclosure provides a manufacturing method of a flexible electrode layer, comprising: forming a first electrode layer on a substrate, the first electrode layer being made of carbon nanotube material and/or graphene material; and performing doping modification on the first electrode layer by using an oxidizing material, to form a second electrode layer.

In another aspect, an embodiment of the present disclosure provides a flexible electrode layer, which is obtained by using the manufacturing method as mentioned above.

In another aspect, an embodiment of the present disclosure provides a manufacturing method of a display substrate, comprising: performing a patterning process on the flexible electrode layer obtained by using the manufacturing method according to claim 1, to obtain a patterned display electrode, wherein, the display electrode comprises: at least one type of a pixel electrode, a common electrode, a touch drive electrode and a touch sensing electrode.

In still another aspect, an embodiment of the present disclosure provides a display substrate, obtained by using the manufacturing method as mentioned above.

In yet another aspect, an embodiment of the present disclosure provides a display device, comprising the display substrate as mentioned above.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a manufacturing flow schematic diagram I of a flexible electrode layer provided by an embodiment of the present disclosure;

FIG. 2 shows a cross-sectional structural diagram of step S01;

FIG. 3 shows a cross-sectional structural diagram of step S02;

FIG. 4 is a flow schematic diagram of step S02 in FIG. 1;

FIG. 5 is a manufacturing flow schematic diagram II of a flexible electrode layer provided by an embodiment of the present disclosure;

FIG. 6 is a flow schematic diagram of step S03 in FIG. 5;

FIG. 7 shows a cross-sectional structural diagram of step S31; and

FIG. 8 shows a cross-sectional structural diagram of step S32.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

In a flexible display, a carbon material such as a carbon nanotube (CNT) having a better flexibility may replace ITO and IZO as a material of an electrode structure.

A thickness of the electrode structure such as a pixel electrode in the flexible display is very small, which is typically 400 Å only; and in order to reduce an overall thickness of the flexible display, and at the same time increase its transmittance, the thickness of the electrode structure such as the pixel electrode should be reduced as much as possible. Thus, when the CNT is applied to the electrode structure such as the pixel electrode, a square resistance (with a symbol of Rs, an expression of Rs=ρ/t; where, ρ is a resistivity of an electrode material, and t is a thickness of an electrode) has a larger value of Rs, and energy consumption is relatively higher, which is not conducive to further development of the flexible display.

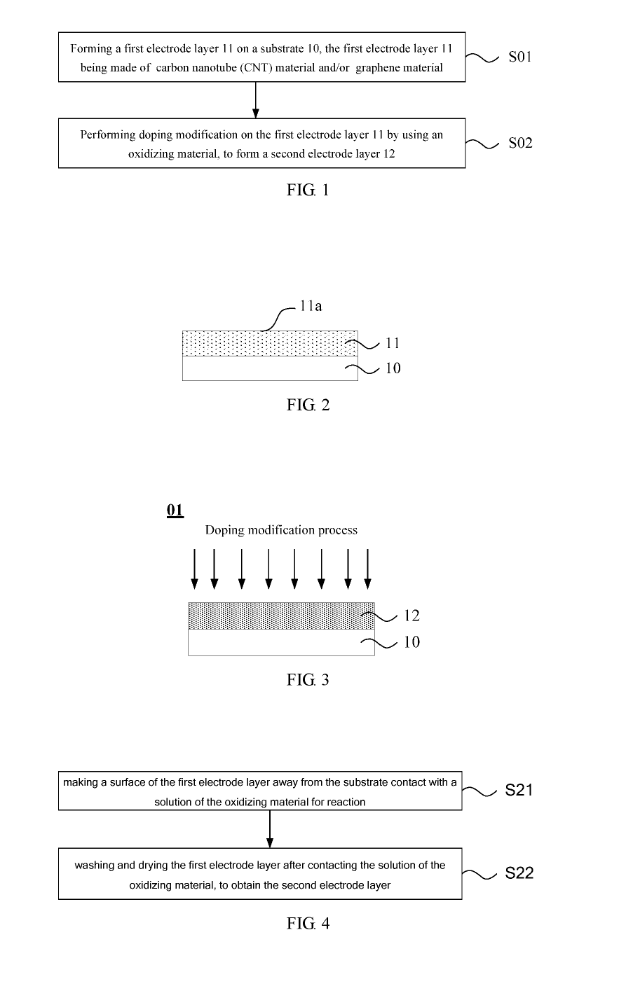

An embodiment of the present disclosure provides a manufacturing method of a flexible electrode layer 01, as shown in FIG. 1, the manufacturing method comprising:

S01: forming a first electrode layer 11 on a substrate 10, the first electrode layer 11 being made of a carbon nanotube (CNT) material and/or a graphene material;

S02: performing doping modification on the first electrode layer 11 by using an oxidizing material, to form a second electrode layer 12.

It should be noted that, firstly, the above-described substrate 10 may be a base substrate made of a flexible material such as stainless steel and a polyester film; and may also be a substrate comprising a base substrate and an array structure layer including a Thin Film Transistor (TFT) formed on the base substrate, which will not be specifically limited, and the suitable substrate 10 as described above may be selected flexibly according to a function of the second electrode layer 12.

Secondly, in the above-described step S01, according to different materials of the first electrode layer 11, the above-described first electrode layer 11 may be formed by a variety of processes.

For example, when the first electrode layer 11 is made of the carbon nanotube material, carbon nanotube dispersion liquid may be coated on the above-described substrate 10, and the above-described first electrode layer 11 is formed by using a washing-drying-film forming manner; or, a curing layer may be firstly coated on the above-described substrate 10, then the carbon nanotube is fabricated on the curing layer by using a film forming process such as a film-drawing manner, and according to a curing performance of a material of the curing layer, the carbon nanotube is fixed by using a corresponding curing process, to form the above-described first electrode layer 11.

Here, the carbon nanotube dispersion liquid refers to a liquid including the carbon nanotube subjected to a dispersion treatment.

When the first electrode layer 11 is made of the graphene material, if lattice constants of the material of the above-described substrate 10 and the graphene match better, the first electrode layer 11 may be formed on the above-described substrate 10 by using a chemical vapor deposition method, a epitaxial growth or the like; or, if the material of the above-described substrate 10 does not match the graphene in the lattice constant, it is difficult to directly form a film on the substrate 10, the first electrode layer 11 having been formed on a base layer may also be transferred onto the above-described substrate 10 in a pattern-transferring manner.

Here, the above-described pattern-transferring process refers to a process of transferring a film layer with a certain pattern formed on an intermediate carrier (for example, the above-described base layer) onto a target carrier (for example, the above-described substrate 10).

Thirdly, in the above-described step S02, the oxidizing material is just a material having oxidizability, i.e., a material having an ability to obtain an electron, which, for example, may include, but is not limited to, at least one material of nitrogen dioxide (NO₂), elemental bromine (Br₂), nitric acid (HNO₃), thionyl chloride (SOCl₂), Nafion and TCNQF₄.

After doping modification is performed on the first electrode layer 11 by using the above-described oxidizing material, a resistivity of the formed second electrode layer 12 may be less than that of the first electrode layer 11.

Since the above-described material has a strong oxidizability, after the first electrode layer 11 is subjected to doping modification, ions may be attached to a surface of the carbon nanotube material and/or the graphene material, to form p-π conjugation within a structure of the first electrode layer 11, which improves a conjugation degree in a structure of the carbon nanotube material and/or the graphene material, and reduces π-π* transition energy of an electron, so that a conductivity (with a symbol of σ, and a unit of s/cm) increases; and since a reciprocal of the conductivity is a resistivity (σ=1/ρ), the resistivity ρ decreases.

Exemplarily, with a case where the first electrode layer 11 is made of the CNT material, and the oxidizing material is HNO₃ as an example, a conductivity of the first electrode layer 11 not subjected to HNO₃ doping modification is tens of to hundreds of s/cm, and a conductivity of the second electrode layer 12 subjected to doping modification may be up to 1.2×10⁴˜9.0×10⁴ s/cm; and correspondingly, a square resistance of the second electrode layer 12 subjected to doping modification may be reduced to 10 Ω/□.

Here, “Ω/□” refers to a unit of the square resistance determined by a probe method, which is used for representing a resistance between one side and an opposing side of any square (i.e., a square, with any side length) of a thin layer material; where, “□” in “Ω/□” represents a square.

Based on this, by using the above-described manufacturing method provided by the embodiment of the present disclosure, doping modification is performed on the first electrode layer 11 made of the carbon nanotube (CNT) material and/or the graphene material, to form the p-π conjugation within the structure thereof, which improves the conjugation degree in the structure of the carbon nanotube material and/or the graphene material, and reduces the π-π* transition energy of the electron, so that the conductivity σ increases; and since the reciprocal of the conductivity is the resistivity σ, the resistivity of the modified second electrode layer 12 decreases significantly, so that the square resistance is relatively small when it is applied to a pixel electrode, a common electrode, a touch electrode and other electrode structures, which meets a requirement of a low resistance value on an electrode structure of a display device, and is conducive to further development of the flexible display.

On the above-described basis, as shown in FIG. 4, the above-described step S02 may further include sub-steps of:

S21: with reference to FIG. 2, contacting an upper surface 11a of the first electrode layer with a solution of the oxidizing material for reaction;

S22: washing and drying the first electrode layer 11 after contacting the solution of the oxidizing material, to obtain the second electrode layer 12.

Here, the upper surface 11a of the first electrode layer refers to a surface of the first electrode layer 11 away from the substrate 10.

With the oxidizing material being HNO₃ as an example, the above-described step S21 may be performed as follows:

Immersing the substrate 10 with the first electrode layer 11 formed thereon into an HNO₃ solution for reaction, wherein the reaction may be performed at room temperature for 5 to 30 mins. Since the first electrode layer 11 is immersed into the HNO₃ solution, surfaces except a surface close to the substrate 10 of the first electrode layer 11 all contact the above-described solution of the oxidizing material, i.e., the HNO₃ solution;

Taking out the first electrode layer 11 having surfaces with the above-described HNO₃ solution, washing it with deionized water, removing unreacted HNO₃ on the surface of the first electrode layer 11; and then, drying it by using a device such as an air knife, to obtain the second electrode layer 12.

Here, the air knife refers to a device which can dry a surface of an object, by certain compressed air.

Alternatively, the above-described step S21 may also be performed as follows:

Spraying the solution of the oxidizing material, i.e., the HNO₃ solution, on the surface of the first electrode layer 11, wherein a reaction may be performed at room temperature for 5 to 30 mins. Since a spraying process is used, only an upper surface 11a of the above-described first electrode layer is in contact with the HNO₃ solution;

Washing the upper surface 11a of the first electrode layer with deionized water, to remove unreacted HNO₃; and then, drying it by using a device such as the air knife, to obtain the second electrode layer 12.

Since the second electrode layer 12 is subjected to the above-described doping modification process, its stability is poorer. After the above-described flexible electrode layer 01 is applied to the electrode structure of the display device, when other structures in the display device are being manufactured, a process in which an acid solvent an alkaline solvent is used will be involved; in addition, the formed second electrode layer 12 may be exposed to high temperature, high humidity, ultraviolet radiation and other process conditions.

Therefore, in order that the above-described flexible electrode layer 01 has a more reliable stability, and meets a requirement of reliability on the electrode structure of the display device; further, as shown in FIG. 5, after the above-described step S02, the manufacturing method may further comprise:

S03: forming a transparent conductive protective layer 13 on an upper surface 12a of the formed second electrode layer.

Here, the upper surface 12a of the second electrode layer refers to a surface of the second electrode layer 12 away from the first electrode layer 11.

The transparent conductive protective layer 13 is made of a transparent and electrically conductive material, which can protect the upper surface 12a of the second electrode layer 12, and meanwhile does not influence transmittance and conductivity when the above-described flexible electrode layer 01 is used as the electrode structure in the display device.

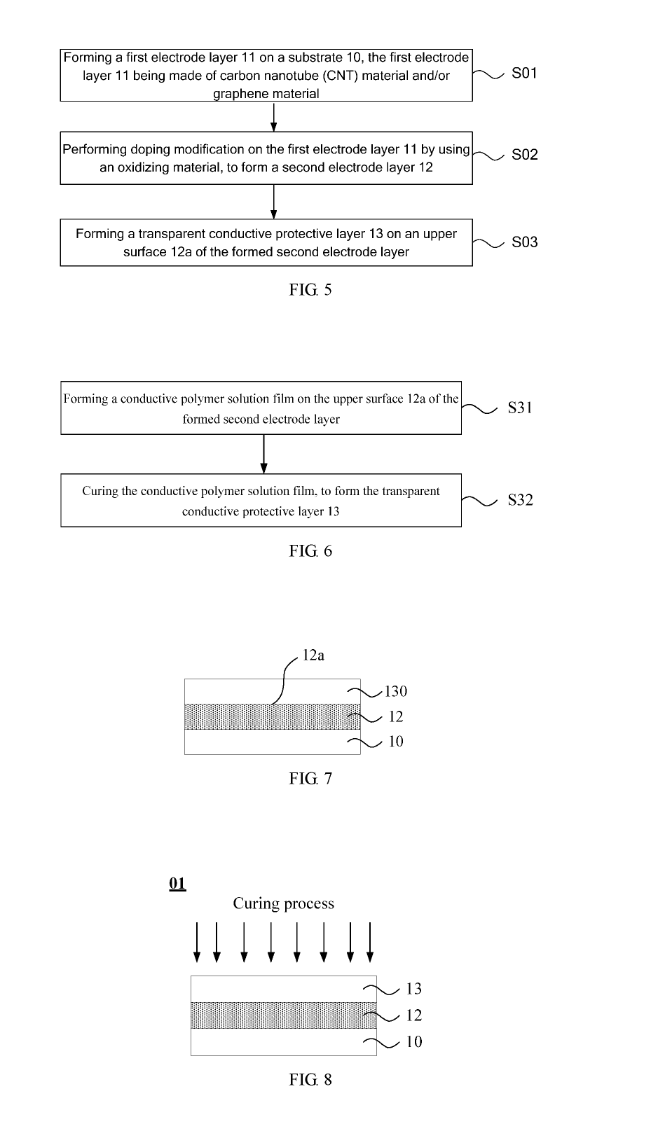

Further, as shown in FIG. 6, the above-described step S03 may exemplarily include sub-steps of:

S31: as shown in FIG. 7, forming a conductive polymer solution film 130 constituted by a transparent conductive polymer solution on the upper surface 12a of the formed second electrode layer;

S32: as shown in FIG. 8, curing the conductive polymer solution film 130 (not shown), to form the transparent conductive protective layer 13.

Therein, in the above-described step S31, the above-described conductive polymer solution film may be formed on the upper surface 12a of the second electrode layer by coating, spray coating and film hanging; and then, the transparent conductive protective layer 13 is formed by drying to cure the conductive polymer solution film.

Here, a solute of the above-described transparent conductive polymer solution may include a conductive polymer, and a solvent may include a room temperature ionic liquid.

It should be noted that, the “room temperature”, is also referred to as a normal temperature or a general temperature; and generally speaking, there are three types of ranges of the room temperature, i.e., (1) 23° C.±2° C.; (2) 25° C.±5° C.; (3) 20° C.±5° C.

The ionic liquid refers to a liquid entirely composed of ions, for example, potassium chloride (KCl) and potassium hydroxide (KOH) at a high temperature are in a liquid state, and at this time, they are ionic liquids. A substance constituted by ions, which is in a liquid state at the room temperature or a temperature near the room temperature, is called as the room temperature ionic liquid. By selecting the room temperature ionic liquid as the solvent, film formation of the above-described conductive polymer solution may be performed at the room temperature, without any additional reaction condition of a high temperature or a low temperature.

Here, the conductive polymer may comprise at least one material of polyacetylene, polythiophene, polypyrrole, polyaniline, polyphenylene, polyphenylene acetylene and polydiacetylene;

Accordingly, the room temperature ionic liquid may comprise at least one material of 1-ethyl-3-methylimidazolium hexafluorophosphate (briefly referred to as [EMIM] PF6), 1-butyl-3-methylimidazolium hexafluorophosphate (briefly referred to as [BMIM] PF6), 1-octyl-3-methylimidazolium hexafluorophosphate (briefly referred to as [OMIM] PF6), 1-ethyl-3-methylimidazolium tetrafluoroborate (briefly referred to as BF6), 1-butyl-3-methylimidazolium trifluoromethanesulfonate (briefly referred to as [BMIM] CF3S03) and chlorinated 1-butyl-3-methylimidazolium salt (briefly referred to as [BMIM] Cl).

Further, in order to improve the conductivity of the above-described flexible electrode layer 01 so as to reduce its resistivity, the solute of the above-described transparent conductive polymer solution further includes: zero dimension nano conductive material and/or one dimension nano conductive material.

Here, the “zero dimension” refers to a point in a three-dimensional space, and the “zero dimension nano conductive material” refers to a conductive material having a geometry size within a nanometer scale range and is granular, which, for example, is a nanosphere; the “one dimension” refers to a line in the three-dimensional space, and the “one dimension nano conductive material” refers to a conductive material whose geometry size in a widthwise direction is limited to 100 nm or less, which, for example, is a nanowire and/or a nanorod.

Since the zero dimension nano conductive material and/or the one dimension nano conductive material have a smaller size, it is conducive to disperse it in the above-described room temperature ionic liquid; and at the same time, the formed transparent conductive protective layer 13 may not have a relatively thickness, so that an overall thickness of the above-described flexible electrode layer 01 is not influenced.

The zero dimension nano conductive material and/or the one dimension nano conductive material may be made of at least one material of gold (Au), silver (Ag), copper (Cu), aluminium (Al), nickel (Ni) and tin (Sn), which may be, for example, a gold nanosphere, a silver nanowire and the like.

Based on the above, an embodiment of the present disclosure further provides a flexible electrode layer 01, and the flexible electrode layer 01 is obtained by using the above-described manufacturing method.

That is, with reference to FIG. 3, the above-described flexible electrode layer 01 comprises a substrate 10, and further comprises a second electrode layer 12 located on the substrate 10, which is obtained after a doping modification process; wherein, the second electrode layer 12 is made of a carbon nanotube (CNT) material and/or a graphene material.

Further, in order to improve stability of the second electrode layer 12 subjected to the doping modification process, with reference to FIG. 8, the above-described flexible electrode layer 01 further comprises a transparent conductive protective layer 13 located on an upper surface 12a of the second electrode layer.

Further, in order to further improve a conductivity of the above-described flexible electrode layer 01 so as to reduce its resistivity, the transparent conductive protective layer 13 further includes: zero dimension nano conductive material and/or one dimension nano conductive material.

The zero dimension nano conductive material and/or the one dimension nano conductive material may be made of at least one material of gold (Au), silver (Ag), copper (Cu), aluminium (Al), nickel (Ni) and tin (Sn), which may be, for example, a gold nanosphere, a silver nanowire and the like.

Based on the above, an embodiment of the present disclosure further provides a manufacturing method of a display substrate, the manufacturing method comprising:

Performing a patterning process on the flexible electrode layer 01 obtained by using the above-described manufacturing method, to obtain a patterned display electrode; wherein, the display electrode includes: at least one type of a pixel electrode, a common electrode, a touch drive electrode and a touch sensing electrode.

That is, a pattern obtained by performing the patterning process on the flexible electrode layer 01 corresponds to a pattern of an electrode structure which needs to be formed, for example, a pixel electrode, a common electrode, a touch drive electrode and a touch sensing electrode.

Here, a typical patterning process refers to a process of exposing and developing photoresist, etching, and removing the photoresist by using one mask.

It should be noted that, with reference to FIG. 5, the above-described patterning process may be performed between step S01 and step S02, that is, the patterning process is performed on the first electrode layer 11, to obtain a corresponding pattern, and the second electrode layer 12 and the transparent conductive protective layer 13 formed thereafter will have a same pattern;

Alternatively, the above-described patterning process may also be performed between step S02 and step S03, that is, the patterning process is performed on the second electrode layer 12, to obtain a corresponding pattern, and the transparent conductive protective layer 13 formed thereafter will have a same pattern;

Alternatively, the above-described patterning process may also be performed after step S03, that is, the patterning process is performed on the transparent conductive protective layer 13 and the second electrode layer 12 below it, to obtain a corresponding pattern.

Based on the above, the performing a patterning process on the flexible electrode layer 01, to obtain a patterned display electrode, includes:

Performing the patterning process on the flexible electrode layer 01 by using laser ablation, to obtain the patterned display electrode.

Here, since the second electrode layer 12 is made of a carbon nanotube (CNT) material and/or a graphene material, and the transparent conductive protective layer 13 is made of an organic material, it is possible to perform the patterning process on the flexible electrode layer 01 by using laser ablation, a major product after laser ablation is carbon dioxide (CO₂), which can volatilize directly, and it is not necessary to remove it by dry etching or wet etching, which, thus, simplifies the manufacturing process.

Exemplarily, with a case where the display electrode obtained by performing the patterning process on the flexible electrode layer 01 obtained by using the above-described manufacturing method is the pixel electrode as an example, a manufacturing process of the above-described display substrate may be:

S41: forming a pattern comprising a gate electrode and a gate line connected with the gate electrode, and a pattern of a common electrode on a substrate made of a flexible material (e.g. a polyester film) by one patterning process;

S42: sequentially depositing a gate insulating layer and an active layer, and forming a pattern of the active layer by one patterning process;

S43: forming a pattern including a source electrode, a drain electrode and a data line connected with the source electrode on the formed active layer;

S44: forming a passivation layer on the pattern including the source electrode, the drain electrode and the data line connected with the source electrode, and forming a through hole exposing the drain electrode in the passivation layer by a patterning process;

S45: forming a pattern of a pixel electrode on the passivation layer, and the pixel electrode being connected with the drain electrode through the above-described through hole.

Therein, in the above-described step S45, an exemplary process of forming the pixel electrode on the passivation layer may comprise steps S01 to S02 shown in FIG. 4, or may comprise steps S01 to S03 shown in FIG. 5, and the patterning process is performed on the formed flexible electrode layer 01 so as to obtain a pattern corresponding to the pixel electrode.

That is, the above-described display substrate is an array substrate in the display device. Of course, the above-described display substrate may also be a color filter substrate having a common electrode; wherein, an exemplary process of forming the common electrode may comprise steps S01 to S02 shown in FIG. 4, or comprise steps S01 to S03 shown in FIG. 5, the patterning process is performed on the formed flexible electrode layer 01 so as to obtain a pattern corresponding to the common electrode, and the specific process will not be repeated.

Based on the above, an embodiment of the present disclosure further provides a display substrate, and the display substrate is obtained by the above-described manufacturing method.

Further, an embodiment of the present disclosure further provides a display device, comprising the above-described display substrate.

Here, the above-described display device may include, but is not limited to, an Organic Light-Emitting Display (OLED), electronic paper, a mobile phone, a tablet computer, a digital photo frame, or any other product or component having a display function.

Based on this, by using the above-described manufacturing method provided by an embodiment of the present disclosure, doping modification is performed on the first electrode layer made of the carbon nanotube (CNT) material and/or the graphene material, to form the p-π conjugation within the structure thereof, which improves the conjugation degree in the structure of the carbon nanotube material and/or the graphene material, and reduces π-π* transition energy of the electron, so that the conductivity a increases; and since the reciprocal of the conductivity is the resistivity ρ, the resistivity of the modified second electrode layer decreases significantly, so that the square resistance is relatively small when it is applied to the pixel electrode, the common electrode, the touch electrode and other electrode structures, which meets the requirement of the low resistance value on the electrode structure of the display device, and is conducive to further development of the flexible display.

It should be noted that, all the drawings of the present disclosure are schematic diagrams of the above-described flexible electrode layer 01 and the display substrate including the flexible electrode layer, just to clearly describe that the present solution reflects structure related with inventive points; and other structures unrelated with the inventive points are existing structures, which are not or only partially reflected in the drawings.

The embodiment of the invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

The present application claims priority of Chinese Patent Application No. 201510247050.4 filed on May 14, 2015, the disclosure of which is incorporated herein by reference in its entirety as part of the present application.

1. A manufacturing method of a flexible electrode layer, comprising:
forming a first electrode layer on a substrate, the first electrode layer being made of carbon nanotube material and/or graphene material; and
performing doping modification on the first electrode layer by using an oxidizing material, to form a second electrode layer.

2. The manufacturing method according to claim 1, wherein, the performing doping modification on the first electrode layer by using an oxidizing material, to form a second electrode layer, comprises:
making a surface of the first electrode layer away from the substrate contact with a solution of the oxidizing material for reaction; and
washing and drying the first electrode layer after contacting the solution of the oxidizing material, to obtain the second electrode layer.

3. The manufacturing method according to claim 2, wherein, the oxidizing material comprises at least one of nitrogen dioxide, elemental bromine, nitric acid, thionyl chloride, nafion and TCNQF₄.

4. The manufacturing method according to claim 1, wherein, after the performing doping modification on the first electrode layer by using an oxidizing material, to form a second electrode layer, the manufacturing method further comprises:
forming a transparent conductive protective layer on a surface of the formed second electrode layer away from the substrate.

5. The manufacturing method according to claim 4, wherein the forming a transparent conductive protective layer on a surface of the formed second electrode layer away from the substrate, comprises:
forming a conductive polymer solution film constituted by a transparent conductive polymer solution on the surface of the formed second electrode layer away from the substrate; and
curing the conductive polymer solution film, to form the transparent conductive protective layer.

6. The manufacturing method according to claim 5, wherein a solute of the conductive polymer solution comprises a conductive polymer, and a solvent comprises a room temperature ionic liquid.

7. The manufacturing method according to claim 6, wherein, the conductive polymer comprises at least one material of polyacetylene, polythiophene, polypyrrole, polyaniline, polyphenylene, polyphenylene acetylene and polydiacetylene;
the room temperature ionic liquid comprises at least one of 1-ethyl-3-methyl imidazolium hexafluorophosphate, 1-butyl-3-methyl imidazolium hexafluorophosphate, 1-octyl-3-methylimidazolium hexafluorophosphate, 1-ethyl-3-methylimidazolium tetrafluoroborate, 1-butyl-3-methylimidazolium trifluoromethanesulfonate and chlorinated 1-butyl-3-methylimidazolium salt.

8. The manufacturing method according to claim 7, wherein, the solute of the conductive polymer solution further comprises: zero dimension nano conductive material and/or one dimension nano conductive material.

9. The manufacturing method according to claim 8, wherein, the zero dimension nano conductive material and/or the one dimension nano conductive material is made of at least one material of gold, silver, copper, aluminium, nickel and tin.

10. The manufacturing method according to claim 2, wherein, the making a surface of the first electrode layer away from the substrate contact with a solution of the oxidizing material for reaction, comprises:
immersing the substrate with the first electrode layer formed thereon into the solution of the oxidizing material for reaction; or
spraying the solution of the oxidizing material on the surface of the first electrode layer.

11. The manufacturing method according to claim 10, wherein, the reaction is performed at a room temperature, and time duration of the reaction is 5 min to 30 min.

12. A flexible electrode layer, obtained by using the manufacturing method according to claim 1.

13. A manufacturing method of a display substrate, comprising:
performing a patterning process on the flexible electrode layer obtained by using the manufacturing method according to claim 1, to obtain a patterned display electrode,
wherein, the display electrode comprises: at least one type of a pixel electrode, a common electrode, a touch drive electrode and a touch sensing electrode.

14. The manufacturing method according to claim 13, wherein, the performing a patterning process on the flexible electrode layer, to obtain a patterned display electrode, comprises:
performing a patterning process on the flexible electrode layer by using laser ablation, to obtain the patterned display electrode.

15. A display substrate, obtained by using the manufacturing method according to claim 13.

16. A display device, comprising the display substrate according to claim 15.
